(19) United States
(12) Patent Application Publication
(10) Pub. No.: US 2026/0269600 A1
(43) Pub. Date: Sep. 10, 2026

(54) IN-VEHICLE SYSTEM AND CONNECTOR

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventor: Shinnosuke NAKAGUCHI, Yokkaichi-shi, Mie (JP)

(73) Assignees: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(21) Appl. No.: 19/149,401

(22) PCT Filed: Jan. 11, 2024
(86) PCT No.: PCT/JP2024/000365

§ 371 Date: Jul. 18, 2025

(30) Foreign Application Priority Data
Jan. 20, 2023 (JP) 2023-007625

(51) Int. Cl. H02H 7/22; B60R 16/02; G01R 19/10; H01R 13/713; H02H 1/00

(52) U.S. Cl. CPC H02H 7/226; B60R 16/0215; G01R 19/10; H01R 13/713; H02H 1/0007; H01R 2201/26

(57) ABSTRACT

An in-vehicle system according to an aspect of the present disclosure is an in-vehicle system including: a power supply device configured to be mounted in a vehicle, receive power from a power source device or a power distribution device, and supply the received power to a vehicle load; and a wire body interposed between the at least one power supply device and the power source device or the power distribution device, and composed of a plurality of small diameter core wires, wherein the wire body is provided with a connector, and the connector is provided with at least one current interruption unit that corresponds to the wire body, and through which a current to the vehicle load connected to the at least one power supply device flows.

### CROSS-REFERENCE TO RELATED APPLICATIONS

This application is the U.S. national stage of PCT/JP2024/000365 filed on Jan. 11, 2024, which claims priority of Japanese Patent Application No. JP2023-007625 filed on Jan. 20, 2023, the contents of which are incorporated herein.

### TECHNICAL FIELD

The present technology relates to an in-vehicle system and a connector.

### BACKGROUND

A vehicle is equipped with in-vehicle electronic control units (ECUs) for controlling in-vehicle equipment, including, for example, a power train system for engine control or the like and a body system for air conditioning control or the like. The vehicle is equipped with a power distribution system (in-vehicle system) including a plurality of power distribution devices that distribute power from a power source to the plurality of in-vehicle ECUs (see e.g., JP 2015-101184A).

However, the in-vehicle system described in JP 2015-101184A does not take into account a configuration in which power is transmitted from a power distribution device to a power supply device (in-vehicle ECU) using small-diameter wires (small-diameter core wires).

The present disclosure has been made in view of such circumstances, and it is an object of the disclosure to provide an in-vehicle system that can transmit power from a power distribution device to a power supply device using small-diameter wires (small-diameter core wires).

### SUMMARY

An in-vehicle system according to an embodiment of the present disclosure is an in-vehicle system including: at least one power supply device configured to be mounted in a vehicle, receive power from a power source device or a power distribution device, and supply the received power to a vehicle load; and a wire body interposed between the at least one power supply device and the power source device or the power distribution device, and composed of a plurality of small-diameter core wires, wherein the wire body is provided with a connector, and the connector is provided with at least one current interruption unit that corresponds to the wire body, and through which a current to the vehicle load connected to the at least one power supply device flows.

### Effects

An in-vehicle system according to an embodiment of the present disclosure can transmit power from a power distribution device to a power supply device using small-diameter wires (small-diameter core wires).

### BRIEF DESCRIPTION OF DRAWINGS

FIG. 1 is a block diagram showing an outline of an in-vehicle system.

FIG. 2 is a perspective view showing a wire harness.

FIG. 3 is a cross-sectional view of the wire harness taken along the line III-III shown in FIG. 2.

FIG. 4 is a block diagram of an exemplary configuration of a connector.

FIG. 5 is a block diagram showing a configuration of a relay connector and power supply devices according to Embodiment 2.

FIG. 6 is a block diagram showing an exemplary configuration of a microcomputer.

FIG. 7 is an explanatory diagram showing an example of a threshold table.

FIG. 8 is a flowchart illustrating an example of processing performed by a control unit of the microcomputer.

FIG. 9 is a block diagram showing an exemplary configuration of a bus bar and so forth according to Embodiment 3.

### DETAILED DESCRIPTION OF PREFERRED EMBODIMENTS

First, embodiments of the present disclosure will be listed and described. At least some of the aspects described below may be combined freely.

In a first aspect, an in-vehicle system according to an aspect of the present disclosure is an in-vehicle system including: at least one power supply device configured to be mounted in a vehicle, receive power from a power source device or a power distribution device, and supply the received power to a vehicle load; and a wire body interposed between the at least one power supply device and the power source device or the power distribution device, and composed of a plurality of small-diameter core wires, wherein the wire body is provided with a connector, and the connector is provided with at least one current interruption unit that corresponds to the wire body, and through which a current to the vehicle load connected to the at least one power supply device flows.

In such an aspect, the power distribution device transmits power to the power supply device (in-vehicle ECU), and the power supply device supplies the power received from the power distribution device to the vehicle load. When the power supply device is provided at a location remote from the power distribution device, a long wire is required to transmit power from the power distribution device to the power supply device. In the case of transmitting power using a plurality of small-diameter wires (which may be, for example, small-diameter core wires of 2 sq or less, or small-diameter core wires of 1 sq or less, or 0.5 sq or less: Increasing the degree of smallness of diameter in such a manner can further improve heat dissipation and bendability), the heat dissipation when dissipating heat generated during power transmission and the bendability to facilitate the installation of wires are enhanced as compared with a case where all the necessary currents are transmitted from the power distribution device to the power supply device using a single wire. By connecting the power distribution device to the connector, connecting the wire body including the plurality of small-diameter wires (small-diameter core wires) to the current interruption units of the connector, and connecting the wire body to the power supply device, it is possible to transmit power from the power distribution device to the power supply device using small-diameter core wires, while maintaining the amount of current transmitted to the power supply device. In addition, the connector has the function of a wire to wire connector (W to W connector) that connects the wires connected to the power distribution device and the wires connected to the vehicle load, and it is therefore possible to eliminate the need for providing a new W to W connector between the power distribution device and the vehicle load connected without the intervention of the power supply device. The plurality of small-diameter core wires included in the wire body are bundled at a location where the wire body is connected to the connector, and a location where the wire body is connected to the power supply device or the vehicle load, and intermediate portions thereof are disposed in a planer fashion. Although one current interruption unit is connected to one power supply device or one vehicle load via one wire body, one power supply device is connected to a plurality of current interruption units. The power distribution device can transmit power to the power supply device such that the power is dispersed in a plurality of wire bodies. When the connector to which the wire body is connected is provided with the current interruption units in this manner, it is possible to eliminate the need for providing each of the plurality of small-diameter wires (small-diameter core wires) constituting the wire body with the current interruption units, thus reducing the number of current interruption units, as well as the number of components and the weight of the product.

In a second aspect, in the in-vehicle system according to an aspect of the present disclosure, the wire body is disposed on left and right sides along an instrument panel area inside an instrument panel of the vehicle, and the at least one power supply device includes a left power supply device disposed on a left side of the wire body, and a right power supply device disposed on a right side thereof.

In such an aspect, the power supply devices are respectively disposed on the left and right sides of an instrument panel area located inside an instrument panel, for example. When the power distribution device is provided in the vicinity of the power supply device on the left side, the length of a wire that transmits power from the power distribution device inside the instrument panel area to the power supply device on the right side increases. Since a current with a value greater than or equal to a predetermined value is required for the power supply device on the right side to be operated, it is necessary to increase the thickness of wire in order to transmit the required current using a single wire. However, due to the limitation on the thickness of the instrument panel area, it is difficult to install a thick wire within the instrument panel area. Therefore, it is desirable to transmit power using a plurality of small-diameter wires in order to reduce the thickness. By connecting the power distribution device to the connector, installing the plurality of small-diameter wires (small-diameter core wire) included in the wire bodies respectively connected to the current interruption units of the connector such that the wire bodies are arranged side by side in the width direction inside the instrument panel area, and connecting the wire bodies to the power supply device, it is possible to transmit power from the power distribution device to the power supply device or the vehicle load using the small-diameter wires (small-diameter core wires), while maintaining the amount of current transmitted to the power supply device.

In a third aspect, in the in-vehicle system according to an aspect of the present disclosure, the connector includes: an input terminal configured to be connected to the power source device or the power distribution device; and output terminals configured to be connected to the at least one power supply device or the vehicle load, the input terminal has a larger size than the output terminals, and the number of the output terminal is larger than a theumber of the input terminals.

In such an aspect, in the connector, the size of the input terminal to which the wires connected to the power distribution device are connected is larger than the size of the output terminals to which the wire body connected to the vehicle load or the power supply device is connected, and the allowable current value is large. In addition, the number of output terminals (output poles) is larger than the number of input terminals (input poles). This enables the connector to output, to many wire bodies separately, a current with a large current value transmitted from the power distribution device.

In a fourth aspect, in the in-vehicle system according to an aspect of the present disclosure, the at least one current interruption unit is mounted on a surface of a substrate included in the connector.

In such an aspect, the current interruption unit of the connector is included in the substrate included in the connector. The current interruption unit can be, for example, a mechanical fuse or a semiconductor fuse. The current interruption unit is switched off when a current having a value greater than or equal to a predetermined current value flows therethrough to interrupt the current, thus making it possible to protect the vehicle load, the wires, and the power supply device.

In a fifth aspect, in the in-vehicle system according to an aspect of the present disclosure, the at least one current interruption unit includes a semiconductor fuse, the at least one power supply device includes a control unit configured to control feeding of power to the vehicle load, and the semiconductor fuse is configured to be switched on or off under the control of the control unit of the at least one power supply device.

In such an aspect, the current interruption unit of the connector is constituted by a semiconductor fuse. Wires through which a current supplied to the vehicle load flows are connected to the semiconductor fuse, and the semiconductor fuse is switched on or off by the control unit of the power supply device. The control unit of the power supply device can switch the semiconductor fuse on or off according to the vehicle load to which a current is supplied.

In a sixth aspect, in the in-vehicle system according to an aspect of the present disclosure, the semiconductor fuse detects a value of a current passed therethrough, the at least one power supply device includes a storage unit configured to store a table in which a threshold for a total current value obtained by summing individual current values detected by the corresponding semiconductor fuse, and the semiconductor fuse to be switched off are associated with each other, the control unit of the at least one power supply device is configured to: obtain the individual current values from a plurality of the semiconductor fuses; calculate the total current value by summing the obtained plurality of the individual current values; reference the table to specify the semiconductor fuse to be switched off based on calculated the total current value; and switch the specified semiconductor fuse off.

In such an aspect, by switching off the semiconductor fuse according to the total current value of the current transmitted to one power supply device, it is possible to prevent an overcurrent from flowing, thus protecting the vehicle load, the wires, and the power supply device. Note that the semiconductor fuse to be switched off based on the total current value may be specified in a random fashion, or may be specified in sequence. A plurality of power supply devices may be configured by a master-slave system. In this case, the power supply device acting as the master may obtain the current values of a semiconductor fuse connected to the power supply device acting as the slave, and switch, based on the obtained current values, a semiconductor fuse connected to the power supply device acting as the slave.

In a seventh aspect, in the in-vehicle system according to an aspect of the present disclosure, the at least one current interruption unit includes a mechanical fuse, and the mechanical fuse is configured to be switched off when an overcurrent flows therethrough.

In such an aspect, at least some of a plurality of current interruption units are constituted by mechanical fuses. The wire body connected to the current interruption unit according to the present aspect transmits a current necessary for the power supply device to be operated. The current flowing through the current interruption unit according to the present aspect is smaller than the current flowing through a current interruption unit through which the current supplied to the vehicle load flows. Accordingly, a low-cost fuse having a relatively low rated current value can be used as the current interruption unit according to the present aspect. The current interruption unit according to the present aspect is on in a normal state, and is switched off when a overcurrent flows therethrough.

In an eighth aspect, in the in-vehicle system according to an aspect of the present disclosure, the small-diameter core wires are covered with an insulating coating, a plurality of the wire bodies are provided side by side to constitute a wire harness, the wire harness includes the insulating coating, and a functional exterior member formed in a sheet shape, and at least part of an overlapping portion of the insulating coating and the functional exterior member is welded.

In such an aspect, it is possible to easily dissipate heat from the wire body. In addition, the wire body has higher bendability than a wire body using large-diameter core wires, and therefore can be easily positioned at the time of placing the connector.

In a ninth aspect, the in-vehicle system according to an aspect of the present disclosure further includes a bus bar configured to be connected to the power source device or the power distribution device, wherein the bus bar includes a substrate including a plurality of the current interruption units.

In such an aspect, a current with a large current value that has been transmitted from the power distribution device via the bus bar can be separately output to many small-diameter core wires.

In a tenth aspect, the in-vehicle system according to an aspect of the present disclosure further includes: the vehicle load configured to be connected to the power source device or the power distribution device; and the wire body interposed between the vehicle load and the power source device or the power distribution device, wherein the connector is provided with at least one current interruption unit that corresponds to the wire body, and through which a current to the vehicle load flows.

In such an aspect, it is possible to transmit power using small-diameter core wires, while maintaining the amount of current transmitted to the vehicle load directly connected to the power source device or the power distribution device.

In an eleventh aspect, a connector according to an aspect of the present disclosure is a connector for use in an in-vehicle system including: at least one power supply device configured to be mounted in a vehicle, receive power from a power source device or a power distribution device, and supply the received power to a vehicle load; and a wire body interposed between the at least one power supply device and the power source device or the power distribution device, and composed of a plurality of small diameter core wires, wherein the wire body is provided with the connector, and the connector is provided with at least one current interruption unit that corresponds to the wire body, and through which a current to the vehicle load connected to the at least one power supply device flows.

In such an aspect, it is possible to transmit power from a power distribution device to a power supply device using small-diameter wires (small-diameter core wires).

Specific examples of a power feeding control apparatus according to embodiments of the present disclosure will be described below with reference to the drawings. It should be noted that the present disclosure is not limited to these examples, but is defined by the claims, and is intended to include all modifications which fall within the scope of the claims and the meaning and scope of equivalents thereof.

### Embodiment 1

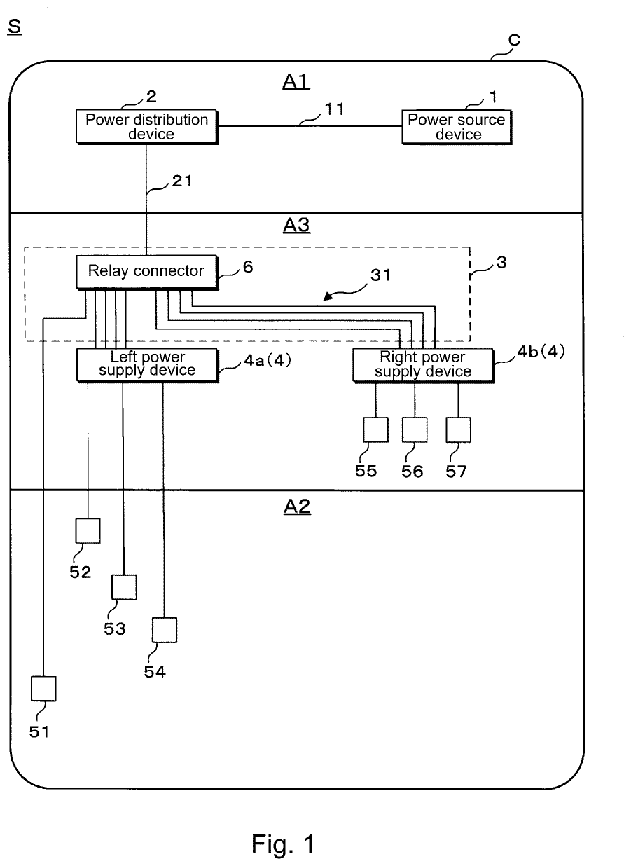

FIG. 1 is a block diagram showing an outline of an in-vehicle system S. The in-vehicle system S is mounted in a vehicle C, and includes a power source device 1, a power distribution device 2, a wire harness 3, at least one power supply device 4, and at least one vehicle load 5. The vehicle C is compartmentalized into a plurality of placement areas, and constituent elements included in the in-vehicle system S are placed in any one of the placement areas.

The plurality of placement areas according to the present embodiment includes an engine room area A1, an instrument panel area A3, and a floor area A2. The engine room area Al indicates an area occupied by an engine room, and the power source device 1 and the power distribution device 2 are placed in the engine room area A1. The power source device 1 is, for example, a battery power source, and transmits power to the power distribution device 2 via a power line 11. The power distribution device 2 is, for example, a relay box, and controls the power transmitted to the power supply device 4, or the power transmitted to a vehicle load 5 (51) connected without the intervention of the power supply device 4. Note that the power supply device 4 or the vehicle load 51 may directly receive power from the power source device 1 without the intervention of the power distribution device 2. The vehicle load 51 connected without the intervention of the power supply device 4 is, for example, an in-vehicle device such as in-vehicle equipment, including, for example, a brake lamp provided at a location remote from the instrument panel area A3, or an in-vehicle ECU.

The floor area A2 indicates an area partitioned by a floor panel, or an internal area of a seat. For example, vehicle loads 5 (52 to 54) including, for example, in-vehicle devices such as a seat drive device, or in-vehicle ECUs are placed in the floor area A2. The instrument panel area A3 indicates an area partitioned by an instrument panel, and a plurality of power supply devices 4 and a wire harness 3 are placed in the instrument panel area A3. In addition, for example, a human machine interface (HMI) device, vehicle loads 5 (55 to 57), including, for example, in-vehicle devices such as an air conditioner and a meter or the like, or in-vehicle ECUs are placed in the instrument panel area A3. Note that the vehicle loads may be placed in the engine room area Al.

In the present embodiment, as the power supply device 4, one power supply device is placed on each of the left side and the right side in the instrument panel area A3. In the following description, the power supply device 4 on the left side is referred to as a left power supply device 4a, and the power supply device on the right side is referred to as a right power supply device 4b. Note that the positions at which the power supply devices 4 are placed are not limited to the left and right sides in the instrument panel area A3, and the power supply devices 4 may be placed on, for example, the front side and the rear side of the vehicle. The number of power supply devices 4 is not limited to two, and three or more power supply devices 4 may be placed in the vehicle C.

The wire harness 3 includes a relay connector 6. The relay connector 6 outputs power received from the power distribution device 2 via a power line 21 to a plurality of wire bodies 31 separately. The details of the relay connector 6 will be described later. The power supply device 4 receives power from the power distribution device 2 via the relay connector 6 and the plurality of wire bodies 31. The vehicle load 51 connected to the power distribution device 2 without the intervention of the power supply device 4 receives power from the power distribution device 2 via the relay connector 6 and a wire body 31. Note that it is also possible to adopt a configuration in which the relay connector 6 is provided outside the wire harness 3, and is connected to the wire harness 3.

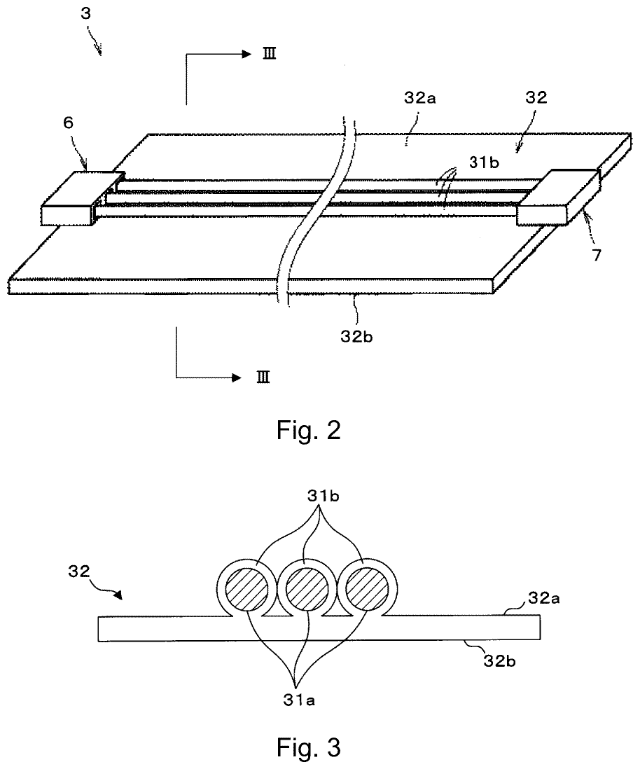

FIG. 2 is a perspective view showing the wire harness 3. FIG. 3 is a cross-sectional view of the wire harness 3 taken along the line III-III shown in FIG. 2. The wire harness 3 includes the wire bodies 31, a functional exterior member 32, the relay connector 6, and a device connector 7. Each of the wire bodies 31 includes a plurality of small diameter core wires 31a, and an insulating coating 31b that covers each of the small-diameter core wires 31a. Each of the small-diameter core wires 31a is formed of a conductive material such as copper or aluminum. The small-diameter core wire 31a in the present embodiment is a solid wire, but may be a twisted wire. It is also possible to adopt a configuration in which the wire bodies 31 each formed of a plurality of small diameter core wires 31a are covered by the insulating coatings 31b. The insulating coating 31b is formed, for example, by extrusion molding a resin such as polyvinyl chloride (PVC), polyethylene (PE), or polypropylene (PP) to the outer circumference of each of the small-diameter core wires 31a.

The functional exterior member 32 is formed of, for example, a sheet material made of polyvinyl chloride (PVC), polyethylene (PE), polypropylene (PP), or a non-woven fabric or the like. The functional exterior member 32 has at least one function selected from soundproofing (muffling, sound absorption, sound insulation, etc.), protection (wear resistance, tensile resistance, penetration resistance, etc.), heat dissipation, shielding, water proofing, and the like for the small-diameter core wires 31a. The functional exterior member 32 in the present embodiment is formed as a rectangular sheet, but may be changed as appropriate according to the routing configuration and the like of the wire bodies 31.

Each of the small-diameter core wires 31a is disposed so as to overlap the functional exterior member 32 in at least a partial area along the longitudinal direction. In the example shown in FIGS. 2 and 3, three small-diameter core wires 31a are illustrated for the sake of convenience of description. However, a larger number of small-diameter core wires 31a can be disposed on the functional exterior member 32. At least part of an overlapping portion of the insulating coatings 31b covering the small-diameter core wires 31a and the functional exterior member 32 is welded by ultrasonic welding, for example. Thus, the wire bodies 31 and the functional exterior member 32 are fixed to each other. Note that the wire bodies 31 and the functional exterior member 32 may be sewn and fixed to each other using a sewing thread.

One end of each of the small-diameter core wires 31a is incorporated into the relay connector 6, and the other end thereof is incorporated into the device connector 7. The plurality of small-diameter core wires 31a are bundled in the relay connector 6 and the device connector 7, thus forming each of the wire bodies 31. Note that the same small-diameter core wires 31a are included in each of the wire bodies 31 inside the relay connector 6 and the device connector 7. The relay connector 6 is connected to the power distribution device 2, and the device connector 7 is connected to the power supply device 4 or the vehicle load 51. The relay connector 6 includes a current interruption unit 62, which will be described later, but does not include the device connector 7. Note that the device connector 7 may have the same configuration as that of the relay connector 6.

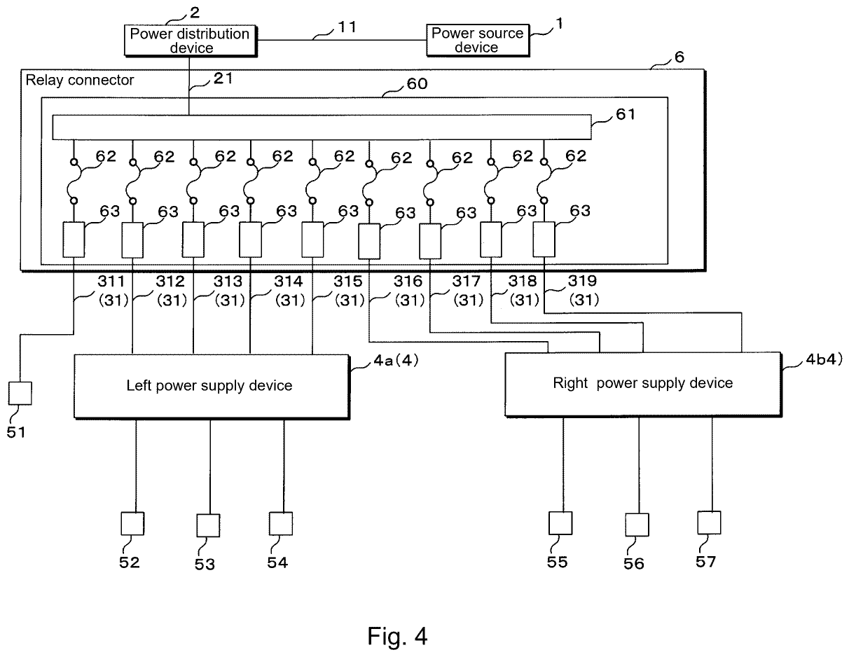

FIG. 4 is a block diagram showing an exemplary configuration of the relay connector 6. The relay connector 6 includes a substrate 60. An input terminal 61, a plurality of current interruption units 62, and a plurality of output terminals 63 are provided (mounted) on a surface of the substrate 60. The input terminal 61 is a terminal to which the power line 21 is connected, and that receives power from the power distribution device 2. Inside the relay connector 6, the plurality of current interruption units 62 are connected to the input terminal 61. In the present embodiment, each of the current interruption units 62 is a mechanical fuse. The current interruption units 62 melt when a current with a value greater than or equal to a rated current value passes therethrough, thereby interrupting the current (being switched off). The current interruption units 62 are connected to the corresponding output terminals 63.

The power that has been input to the input terminal 61 is applied in a dispersed manner to the plurality of current interruption units 62, and is transmitted from the output terminals 63 connected to the corresponding current interruption units 62. That is, the number of the input terminals 61 included in the relay connector 6 is one, and the number of the output terminals 63 is the same as the number of the current interruption units 62, and is one or more. The current value of the power transmitted from each of the output terminals 63 is lower than the current value of the power input to the input terminal 61, and therefore the input terminal 61 has a larger size and a larger allowable current value than the output terminals 63.

The wire bodies 31 are respectively connected to the output terminals 63. In the present embodiment, the wire bodies 31 include wire bodies 311 to 319. The wire bodies 31 are connected to the vehicle load 51, the left power supply device 4a, or the right power supply device 4b. In the present embodiment, the wire body 311 is connected to the vehicle load 51, the wire bodies 312 to 315 are connected to the left power supply device 4a, and the wire bodies 316 to 319 are connected to the right power supply device 4b.

With the above-described configuration, it is possible, using the small-diameter core wires 31a having excellent heat dissipation and bendability, to transmit power from the power distribution device 2 to the power supply device 4 or the vehicle load 51, while maintaining the amount of current transmitted to the power supply device 4 or the vehicle load 51.

### Embodiment 2

In Embodiment 1, the current interruption units 62 included in the relay connector 6 are mechanical fuses. However, the current interruption units 62 may be semiconductor fuses.

In the following, aspects in which Embodiment 2 differs from Embodiment 1 will be described. Components of Embodiment 2 other than those described below are the same as those of Embodiment 1. Therefore, the components that are the same as those of Embodiment 1 are denoted by the same reference numerals as Embodiment 1, and the description thereof has been omitted.

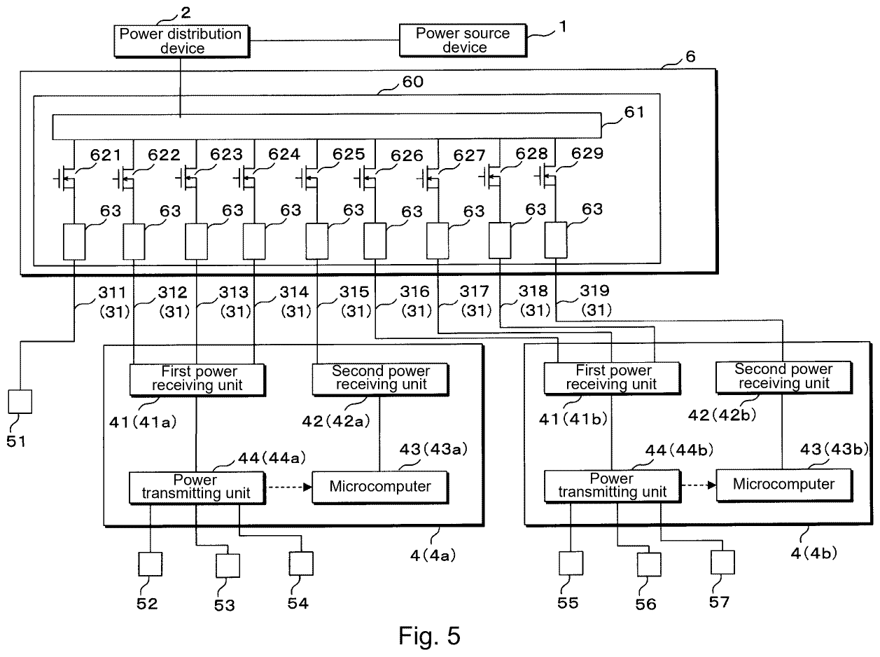

FIG. 5 is a block diagram showing an exemplary configuration of a relay connector 6, power supply devices 4, and so forth according to Embodiment 2. The power supply devices 4 according to Embodiment 2 each include a first power receiving unit 41, a second power receiving unit 42, a microcomputer 43, and a power transmitting unit 44. Note that a left power supply device 4a and a right power supply device 4b have the same configuration in the present embodiment.

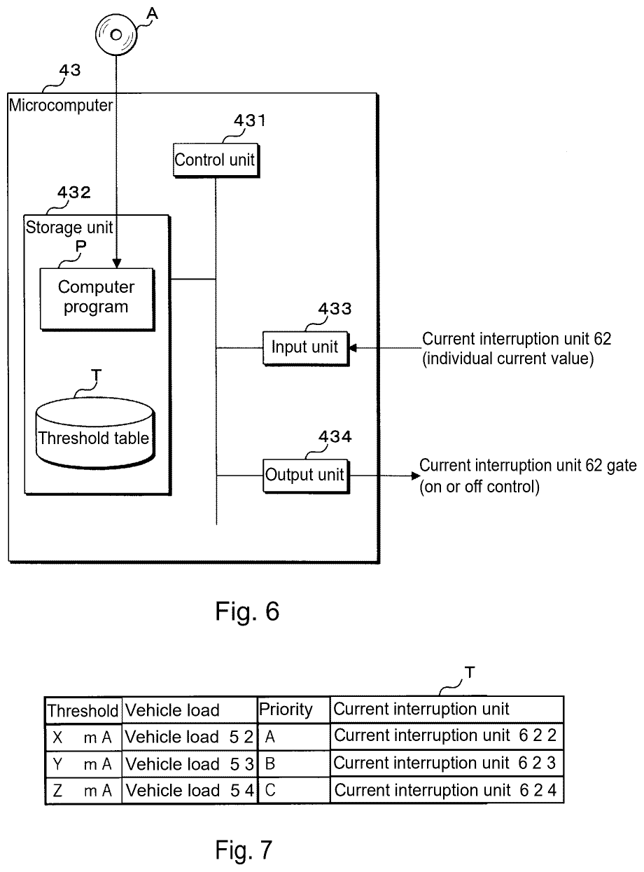

Each current interruption unit 62 of the relay connector 6 according to the present embodiment is a semiconductor fuse constituted by an N-channel FET, for example. Note that the current interruption unit 62 may be, for example, a P-channel FET, a thyristor, a bipolar transistor, or an intelligent power device (IPD) including a FET. The current interruption unit 62 is provided on a substrate 60 such that a drain thereof is connected to the input terminal 61, and a source thereof is connected the corresponding output terminal 63. The current interruption unit 62 includes a current detection function and thus is capable of detecting the value of a current passed therethrough, and outputs the detected current value to the power supply device 4. The current interruption unit 62 has a gate connected to the microcomputer 43 of the corresponding power supply device 4 (see FIG. 6), and is brought into an electrically conductive on state in response to a high-level voltage being applied to the gate, and is switched to an electrically non-conductive off state in response to a low-level voltage applied thereto.

Each microcomputer 43 is capable of obtaining the value of a current flowing through the corresponding current interruption unit 62 and the value of a current transmitted from the corresponding power transmitting unit 44 to the corresponding vehicle loads 5. If the value of a current flowing through the corresponding current interruption unit 62 or the value of current transmitted to the corresponding vehicle load 5 is greater than or equal to a threshold, the microcomputer 43 switches the current interruption unit 62 off, thus interrupting the current.

The device connector 7 (see FIG. 2) is connected to the first power receiving unit 41 and the second power receiving unit 42. The first power receiving unit 41 receives power that is to be supplied to the vehicle load 5 by the corresponding power supply device 4, and transmits the received power to the corresponding power transmitting unit 44. The second power receiving unit 42 receives power for operating the corresponding microcomputer 43, and transmits the received power to the microcomputer 43.

Each of the power transmitting units 44 transmits the power received from the first power receiving unit 41 to the vehicle loads 5. In addition, the power transmitting unit 44 includes a current detection unit (not shown), detects the current values of the power that energizes the power transmitting unit 44 and is transmitted to the vehicle loads 5, and outputs the detected current values to the corresponding microcomputer 43. In the present embodiment, a power transmitting unit 44a of the left power supply device 4a is connected to vehicle loads 52 to 54, and detects the current values (transmission current values) of the power transmitted to the vehicle loads 52 to 54. A power transmitting unit 44b of the right power supply device 4b is connected to vehicle loads 55 to 57, and detects the current values (transmission current values) of the power transmitted to the vehicle loads 55 to 57.

The current interruption units 62 according to the present embodiment include current interruption units 621 to 629. The current interruption unit 621 is connected to the vehicle load 51. The current interruption units 622 to 624 are connected to the first power receiving unit 41 (41a) of the left power supply device 4a. The current interruption unit 625 is connected to the second power receiving unit 42 (42a) of the left power supply device 4a. The current interruption units 626 to 628 are connected to the first power receiving unit 41 (41b) of the right power supply device 4b. The current interruption unit 629 is connected to the second power receiving unit 42 (42b) of the right power supply device 4b. The current interruption units 622 to 624 connected to the first power receiving unit 41a of the left power supply device 4a are switched on or off by the microcomputer 43a of the left power supply device 4a. The current interruption units 625 and 629 connected to the second power receiving unit 42 are not controlled by the microcomputers 43 of the power supply devices 4, and interrupt an overcurrent when the overcurrent flows therethrough. The current interruption units 625 and 629 connected to the second power receiving units 42 may be mechanical fuses.

In the present embodiment, the current interruption units 622 to 624 are controlled by the microcomputer 43a of the left power supply device 4a, and the current interruption units 626 to 628 are controlled by the microcomputer 43b of the right power supply device 4b. However, the present disclosure is not limited thereto. For example, the left power supply device 4a and the right power supply device 4b are configured by a master-slave system in which the left power supply device 4a acts as the master. In this case, the microcomputer 43a of the left power supply device 4a may obtain the current values detected by the current interruption units 626 to 628 connected to the first power receiving unit 41b of the right power supply device 4b, and perform control to switch the current interruption units 626 to 628 on or off.

FIG. 6 is a block diagram showing an exemplary configuration of a microcomputer 43. The microcomputer 43 includes a control unit 431, a storage unit 432, an input unit 433, and an output unit 434. The control unit 431 is constituted by a central processing unit (CPU), a micro processing unit (MPU), or the like, and is configured to perform various types of control processing and arithmetic processing and the like by reading out a program P (program product) and data stored in advance in the storage unit 432. The control unit 431 is not limited to a software processing unit such as a CPU that performs software processing, but may also include a hardware processing unit, such as an FGPA, an ASIC, or an SOC, that performs various types of control processing and arithmetic processing and the like through hardware processing.

The storage unit 432 is constituted by a volatile memory device such as a random access memory (RAM) or a nonvolatile memory device such as a read only memory (ROM), an electrically erasable programmable ROM (EEPROM), a flash memory, or the like, and a program P (program product) and a threshold table T are stored in advance in the storage unit 432. The program P (program product) stored in the storage unit 432 may be a program P (program product) read out from a recording medium A that can be read by the power supply device 4. Also, the program P may be a program P (program product) downloaded from an external computer (not shown) connected to a communication network (not shown) and stored in the storage unit 432. The details of the threshold table T will be described later.

Current values (individual current values) detected by the current interruption unit 62 connected to the first power receiving unit 41 are input to the input unit 433. The input unit 433 notifies the input individual current values to the control unit 431.

The output unit 434 outputs a signal indicating an instruction to switch the current interruption unit 62 on or off. The control unit 431 instructs the output unit 434 to switch the current interruption unit 62 on or off. In accordance with the instruction by the control unit 431, the output unit 434 switches the signal to be output to the current interruption unit 62. Thus, the current interruption unit 62 is switched on or off. Specifically, the output unit 434 switches the current interruption unit 62 on by outputting a high-level voltage to the gate of the current interruption unit 62, and switches the current interruption unit 62 off by outputting a low-level voltage to the gate of the current interruption unit 62.

FIG. 7 is an explanatory diagram showing an example of the threshold table T. Note that a threshold table T stored in the microcomputer 43a of the left power supply device 4a is illustrated as the threshold table T shown in FIG. 7. In the threshold table T, for a total current value obtained by summing the individual current values obtained by the control unit 431 from the current interruption units 62, the current interruption units 62 corresponding to the vehicle loads 5 to which the supply of power is to be stopped are recorded. FIG. 7 shows the threshold table T stored in the left power supply device 4a. Management items (fields) of the threshold table T include, for example, a threshold field, a vehicle load field, a priority field, and a current interruption unit field. In the threshold field, a threshold for the total current value that switches the current interruption unit 62 off is stored. In the vehicle load field, a vehicle load to which the supply of power is to be stopped if the total current value exceeds the threshold stored in the threshold field is stored. In the present embodiment, X mA is the lowest value, and Z mA is the highest value. In the priority field, a priority indicating the necessity for supplying power to each of the vehicle loads is stored. The priority is assigned to each of the vehicle loads in accordance with, for example, Automotive Safety Integrity Level (ASIL), and is classified into D, C, B, and A in descending order of priority. The higher the priority of a vehicle load 5, the higher the necessity for supplying power to operate the vehicle load 5. Note that in the present embodiment, priority C is assigned to the vehicle load 52, priority B is assigned to the vehicle load 53, and priority A is assigned to the vehicle load 54. In the threshold table T, a vehicle load 5 with a low priority is stored in association with a low threshold. In the current interruption unit field, a current interruption unit 62 through which a current supplied to a vehicle load 5 stored in the vehicle load field is passed is stored.

The control unit 431 of the microcomputer 43 obtains individual current values from the current interruption units 62, and calculates a total current value by summing the obtained individual current values. The control unit 431 references the threshold table T to specify the current interruption unit 62 to be switched off. Note that if the total current value is lower than the lowest threshold stored in the threshold table T, the control unit 431 does not switch any of the current interruption units 62 off. The control unit 431 switches off all the current interruption units 62 corresponding to the vehicle loads 5 having a priority less than or equal to the priority of the vehicle load 5 corresponding to the total current value. That is, the supply of power to the vehicle loads 5 is stopped according to the total current value in ascending order of priority. For example, in the example shown in FIG. 7, if the total current value is greater than or equal to Y mA and less than Z mA, the current interruption unit 623 corresponding to the vehicle load 53, and the current interruption unit 622 corresponding to the vehicle load 52 having a lower priority than the vehicle load 53 are switched off.

The control unit 431 of the microcomputer 43 obtains a transmission current value from the power transmitting unit 44, for example, if the total current value is lower than the lowest threshold stored in the threshold table T, and references the threshold table T to specify the current interruption unit 62 to be switched off based on the obtained transmission current value in the same manner as described above. Note that the control unit 431 may reference a table different from the threshold table T to specify the current interruption unit 62 to be switched off based on the transmission current value.

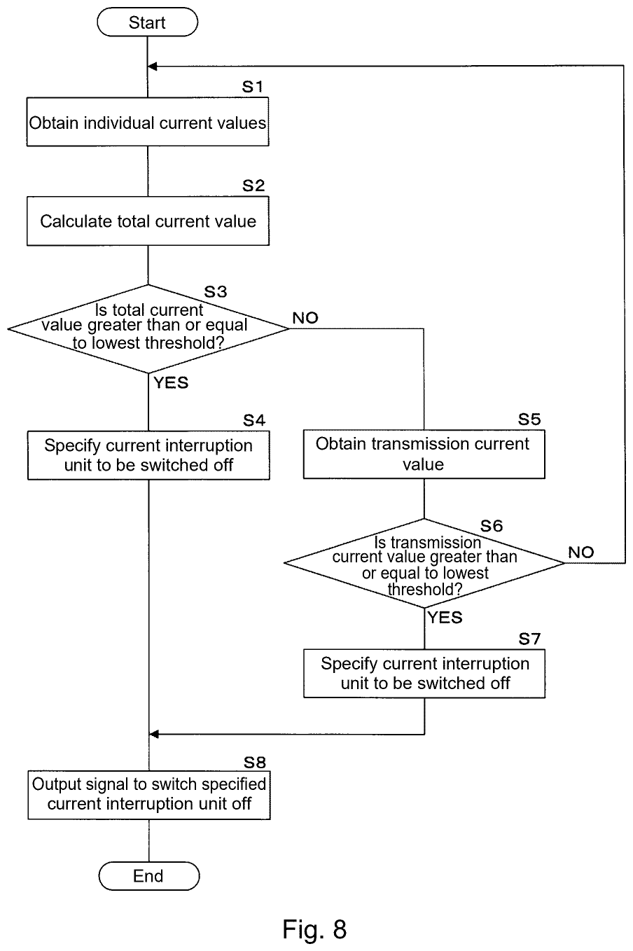

FIG. 8 is a flowchart illustrating an example of processing performed by the control unit 431 of the microcomputer 43. For example, when power is transmitted to the microcomputer 43 from the second power receiving unit 42, the control unit 431 of the microcomputer 43 starts the following processing.

The control unit 431 obtains individual current values from the current interruption unit 62 (S1). The control unit 431 calculates a total current value by summing the obtained individual current values (S2). The control unit 431 determines whether the total current value is greater than or equal to the lowest threshold stored in the threshold table T (S3). If the total current value is greater than or equal to the lowest threshold stored in the threshold table T (S3; YES), the control unit 431 references the threshold table T to specify the current interruption unit 62 to be switched off based on the total current value (S4).

If the total current value is lower than the lowest threshold stored in the threshold table T (S3: NO), the control unit 431 obtains a transmission current value from the power transmitting unit 44 (S5). The control unit 431 determines whether the transmission current value is greater than or equal to the lowest threshold stored in the threshold table T (S6). If the transmission current value is less than the lowest threshold stored in the threshold table T (S6: NO), the control unit 431 returns the processing to S1. If the transmission current value is greater than or equal to the lowest threshold stored in the threshold table T (S6: YES), the control unit 431 references the threshold table T to specify the current interruption unit 62 to be switched off based on the transmission current value (S7).

After specifying the current interruption unit 62 to be switched off in S4 or S7, the control unit 431 causes the output unit 434 to output a signal for switching the specified current interruption unit 62 off (S8), and ends the processing.

### Embodiment 3

In Embodiment 1, the relay connector 6 includes the substrate 60 including the current interruption units 62. However, the present disclosure is not limited thereto. The power distribution device 2 may transmit power to the relay connector 6 via a bus bar, and the bus bar may include a substrate including interruption units.

In the following, aspects in which Embodiment 3 differs from Embodiment 1 will be described. Components of Embodiment 3 other than those described below are the same as those of Embodiment 1. Therefore, the components that are the same as those of Embodiment 1 are denoted by the same reference numerals as Embodiment 1, and the description thereof has been omitted.

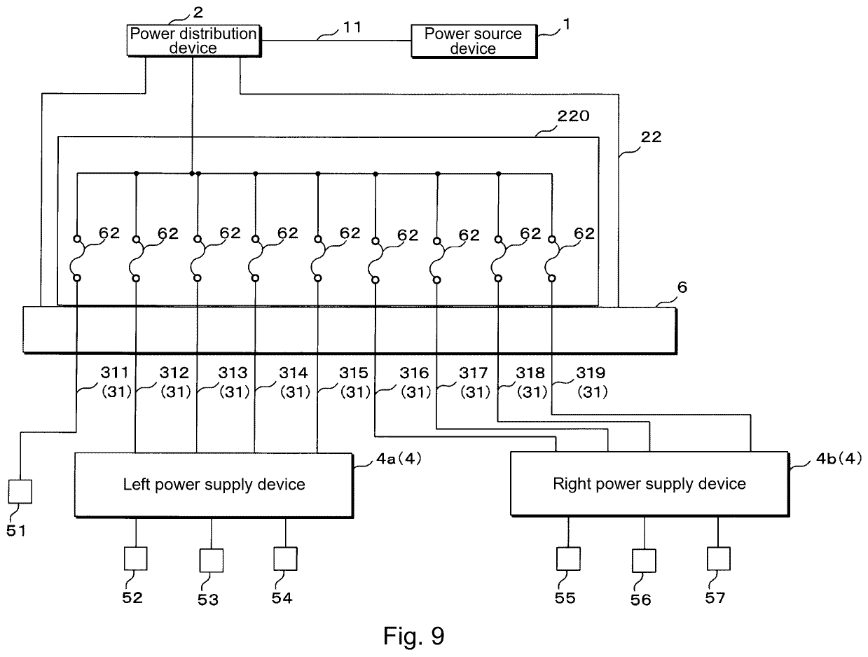

FIG. 9 is a block diagram showing an exemplary configuration of a bus bar 22 and so forth according to Embodiment 3. The bus bar 22 is connected to the power distribution device 2 and the relay connector 6, and current to be transmitted from the power distribution device 2 to the relay connector 6 is passed through the bus bar 22. The bus bar 22 includes a substrate 220. The substrate 220 includes a plurality of current interruption units 62. The current to be transmitted from the power distribution device 2 is passed through the plurality of current interruption units 62 in a dispersed manner. The current interruption units 62 are connected to the corresponding wire bodies 31. Each of the wire bodies 31 is connected to the vehicle load 51, the left power supply device 4a, or the right power supply device 4b via the relay connector 6.

It should be appreciated that the embodiments disclosed herein are to be construed in all respects as illustrative and not limiting. The technical features described in relation to the embodiments can be combined with each other. The scope of the present disclosure is intended to include all modifications within a meaning and scope equivalent to the scope of claims. Some or all of the independent claims and their dependent claims described in the claims can be combined together, regardless of their dependent relationships. Furthermore, a form (multiple dependent claim form) in which a claim dependent on two or more other claims is described is used in the claims; however, the claim form is not limited thereto. The present disclosure may be described using a form (multi-multi dependent claim form) in which a multiple dependent claim is dependent on at least one multiple dependent claim.

1. An in-vehicle system comprising:
at least one power supply device configured to be mounted in a vehicle, receive power from a power source device or a power distribution device, and supply the received power to a vehicle load; and
a wire body interposed between the at least one power supply device and the power source device or the power distribution device, and composed of a plurality of small-diameter core wires, wherein
the wire body is provided with a connector, and
the connector is provided with at least one current interruption unit that corresponds to the wire body, and through which a current to the vehicle load connected to the at least one power supply device flows.

2. The in-vehicle system according to claim 1, wherein
the wire body is disposed on left and right sides along an instrument panel area inside an instrument panel of the vehicle, and
the at least one power supply device includes a left power supply device disposed on a left side of the wire body, and a right power supply device disposed on a right side thereof.

3. The in-vehicle system according to claim 1, wherein
the connector includes:
an input terminal configured to be connected to the power source device or the power distribution device; and
output terminals configured to be connected to the at least one power supply device or the vehicle load,
the input terminal has a larger size than the output terminals, and
a number of the output terminal is larger than a number of the input terminals.

4. The in-vehicle system according to claim 1, wherein
the at least one current interruption unit is mounted on a surface of a substrate included in the connector.

5. The in-vehicle system according to claim 4, wherein
the at least one current interruption unit includes a semiconductor fuse,
the at least one power supply device includes a control unit configured to control feeding of power to the vehicle load, and
the semiconductor fuse is configured to be switched on or off under the control of the control unit of the at least one power supply device.

6. The in-vehicle system according to claim 5, wherein
the semiconductor fuse detects a value of a current passed therethrough,
the at least one power supply device includes a storage unit configured to store a table in which a threshold for a total current value obtained by summing individual current values detected by the corresponding semiconductor fuse, and the semiconductor fuse to be switched off are associated with each other,
the control unit of the at least one power supply device is configured to:
obtain the individual current values from a plurality of the semiconductor fuses;
calculate the total current value by summing the obtained plurality of the individual current values;
reference the table to specify the semiconductor fuse to be switched off based on calculated the total current value; and
switch the specified semiconductor fuse off.

7. The in-vehicle system according to claim 4, wherein
the at least one current interruption unit includes a mechanical fuse, and
the mechanical fuse is configured to be switched off when an overcurrent flows therethrough.

8. The in-vehicle system according to claim 1, wherein
the small-diameter core wires are covered with an insulating coating,
a plurality of the wire bodies are provided side by side to constitute a wire harness,
the wire harness includes the insulating coating, and a functional exterior member formed in a sheet shape, and
at least part of an overlapping portion of the insulating coating and the functional exterior member is welded.

9. The in-vehicle system according to claim 1, further including;
a bus bar configured to be connected to the power source device or the power distribution device, wherein
the bus bar includes a substrate including a plurality of the current interruption units.

10. The in-vehicle system according to claim 1, further including;
the vehicle load configured to be connected to the power source device or the power distribution device; and
the wire body interposed between the vehicle load and the power source device or the power distribution device, wherein
the connector is provided with at least one current interruption unit that corresponds to the wire body, and through which a current to the vehicle load flows.

11. A connector for use in an in-vehicle system including:
a power supply device configured to be mounted in a vehicle, receive power from a power source device or a power distribution device, and supply the received power to a vehicle load; and
a wire body interposed between the at least one power supply device and the power source device or the power distribution device, and composed of a plurality of small-diameter core wires, wherein
the wire body is provided with the connector, and
the connector comprises at least one current interruption unit that corresponds to the wire body, and through which a current to the vehicle load connected to the at least one power supply device flows.

12. The in-vehicle system according to claim 2, wherein
the connector includes:
an input terminal configured to be connected to the power source device or the power distribution device; and
output terminals configured to be connected to the at least one power supply device or the vehicle load,
the input terminal has a larger size than the output terminals, and
a number of the output terminal is larger than a number of the input terminals.

13. The in-vehicle system according to claim 2, wherein
the at least one current interruption unit is mounted on a surface of a substrate included in the connector.

14. The in-vehicle system according to claim 2, wherein
the small-diameter core wires are covered with an insulating coating,
a plurality of the wire bodies are provided side by side to constitute a wire harness,
the wire harness includes the insulating coating, and a functional exterior member formed in a sheet shape, and
at least part of an overlapping portion of the insulating coating and the functional exterior member is welded.

15. The in-vehicle system according to claim 2, further including;
a bus bar configured to be connected to the power source device or the power distribution device, wherein
the bus bar includes a substrate including a plurality of the current interruption units.

16. The in-vehicle system according to claim 2, further including;
the vehicle load configured to be connected to the power source device or the power distribution device; and
the wire body interposed between the vehicle load and the power source device or the power distribution device, wherein
the connector is provided with at least one current interruption unit that corresponds to the wire body, and through which a current to the vehicle load flows.
